(19) United States
(12) Patent Application Publication
(10) Pub. No.: US 2015/0137344 A1
(43) Pub. Date: May 21, 2015

(54) SEMICONDUCTOR DEVICE AND METHOD FOR MANUFACTURING SAME

(71) Applicant: KABUSHIKI KAISHA TOYOTA JIDOSHOKKI, Kariya-shi (JP)

(72) Inventors: Shogo MORI, Aichi-ken (JP); Yuri OTOBE, Aichi-ken (JP); Shinsuke NISHI, Aichi-ken (JP)

(73) Assignee: KABUSHIKI KAISHA TOYOTA JIDOSHOKKI, Kariya-shi (JP)

(21) Appl. No.: 14/543,108

(22) Filed: Nov. 17, 2014

(30) Foreign Application Priority Data
Nov. 19, 2013 (JP) 2013-238972

(51) Int. Cl. H01L 23/367; H01L 21/56; H01L 23/00; H01L 23/31

(52) U.S. Cl. CPC H01L 23/3675; H01L 23/3142; H01L 21/56; H01L 24/83; H01L 24/33; H01L 2924/13055; H01L 2924/13091; H01L 2224/32225
USPC 257/712; 438/122

(57) ABSTRACT

A semiconductor device has a circuit board including an insulation layer, a wiring layer formed on one surface of the insulation layer, and a buffer layer formed on the other surface of the insulation layer, a semiconductor element bonded to the wiring layer, a radiator member bonded to the buffer layer of the circuit board, and a resin member to seal the semiconductor element and an entire surface of the circuit board including an outer peripheral surface of the buffer layer in the circuit board. A method for manufacturing the semiconductor device includes bonding the buffer layer of the circuit board to the radiator member, bonding the semiconductor element to the wiring layer of the circuit board, and sealing the semiconductor element and an entire surface of the circuit board including an outer peripheral surface of the buffer layer in the circuit board with resin after the two bonding steps.

### BACKGROUND OF THE INVENTION

The present invention relates to a semiconductor device and a method for manufacturing same.

Japanese Patent Application Publication No. 2012-119597 discloses a semiconductor device including a bonding layer, a bonded layer, an insulation layer made of an organic resin as base material, a metal layer, and a semiconductor element which are mounted on a cooling device. A laminate including a bonded layer, an insulation layer and a metal layer is provided for one or a plurality of semiconductor elements and mounted on a metal base through the bonding layer and the bonded layer, the insulation layer, the metal layer, and the semiconductor element are sealed by a resin mold as shown in drawings of the above-cited publication.

In the structure shown in the drawings of the above-cited publication, a crack or a break tends to occur in insulation layers and bonding layer due to the difference in the linear expansion coefficients between the insulation layers and a metal base.

The present invention is directed to providing a semiconductor device that reduces the stress applied to insulation layers in a circuit board and also a method for manufacturing such semiconductor device.

### SUMMARY OF THE INVENTION

In accordance with an aspect of the present invention, a semiconductor device has a circuit board including an insulation layer, a wiring layer formed on one surface of the insulation layer, and a buffer layer formed on the other surface of the insulation layer, a semiconductor element bonded to the wiring layer, a radiator member bonded to the buffer layer of the circuit board, and a resin member to seal the semiconductor element and an entire surface of the circuit board including an outer peripheral surface of the buffer layer in the circuit board. A method for manufacturing a semiconductor device includes providing a radiator member, providing a circuit board including an insulation layer, a wiring layer formed on one surface of the insulation layer, and a buffer layer formed on the other surface of the insulation layer, bonding the buffer layer of the circuit board to the radiator member, bonding the semiconductor element to the wiring layer of the circuit board, and sealing the semiconductor element and an entire surface of the circuit board including an outer peripheral surface of the buffer layer in the circuit board with resin after the two bonding steps.

Other aspects and advantages of the invention will become apparent from the following description, taken in conjunction with the accompanying drawings, illustrating by way of example the principles of the invention.

### BRIEF DESCRIPTION OF THE DRAWINGS

The invention together with objects and advantages thereof, may best be understood by reference to the following description of the presently preferred embodiments together with the accompanying drawings in which:

FIG. 1 is a schematic plan view of a semiconductor device according to an embodiment of the present invention;

FIG. 2 is a schematic sectional view taken along the A-A line of FIG. 1;

FIG. 3 is a schematic plan view of the semiconductor device of FIG. 1 without a resin mold;

FIG. 4 is a schematic sectional view taken along the B-B line of FIG. 3;

FIG. 5 is a circuit diagram showing an electrical configuration of the semiconductor device of FIG. 1;

FIG. 6 is a schematic sectional view of a semiconductor device according to another embodiment of the present invention;

FIG. 7 is a schematic sectional view of a semiconductor device according to still another embodiment of the present invention; and

FIG. 8 is a schematic plan view of a semiconductor device according to yet another embodiment of the present invention.

### DETAILED DESCRIPTION OF THE EMBODIMENTS

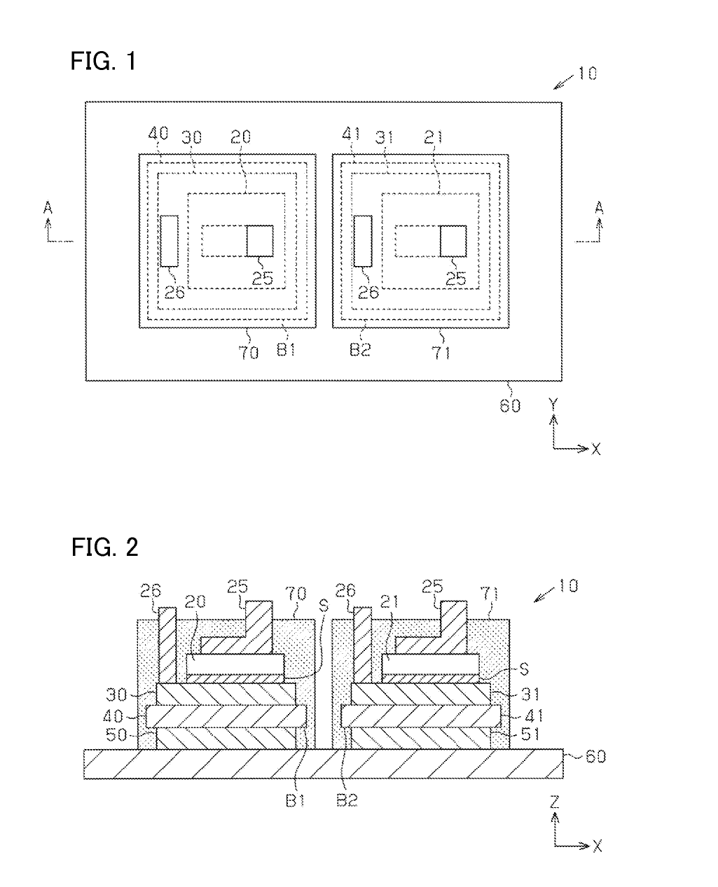

The following will describe an embodiment of the present invention with reference to FIGS. 1 through 5. In the drawings, the horizontal plane is defined by X-Y coordinates and the vertical direction is defined by Z coordinate.

Referring to FIGS. 1 and 2, the semiconductor device that is designated by reference numeral 10 includes semiconductor elements 20, 21, circuit boards B1, B2, and a radiator plate 60. The circuit board B1 includes a ceramic layer 40 having on one surface thereof a wiring layer 30 and on the other surface thereof a buffer layer 50. The semiconductor element 20 is soldered to the wiring layer 30 through a solder layer S. The circuit board B2 includes a ceramic layer 41 having on one surface thereof a wiring layer 31 and on the other surface thereof a buffer layer 51. The semiconductor element 21 is soldered to the wiring layer 31 through the solder layer S.

The radiator plate 60 is rectangular in shape in plan view and made of aluminum. The buffer layers 50, 51 are formed by a plate of high-density and soft aluminum or a perforated aluminum plate.

The buffer layer 50 of the circuit board B1 is bonded to the radiator plate 60. The buffer layer 51 of the circuit board B2 is bonded to the radiator plate 60 at a position spaced apart from the circuit board B1 in X direction.

An electrode 25 is bonded at one end thereof on the upper surface of the semiconductor element 20 and the other end of the electrode 25 extends upward. An electrode 26 is bonded at one end thereof on the upper surface of the wiring layer 30 and the other end of the electrode 26 extends upward. Similarly, the electrode 25 is bonded at one end thereof on the upper surface of the semiconductor element 21 and the other end of the electrode 25 extends upward. The electrode 26 is bonded at one end thereof on the upper surface of the wiring layer 31 and the other end of the electrode 26 extends upward.

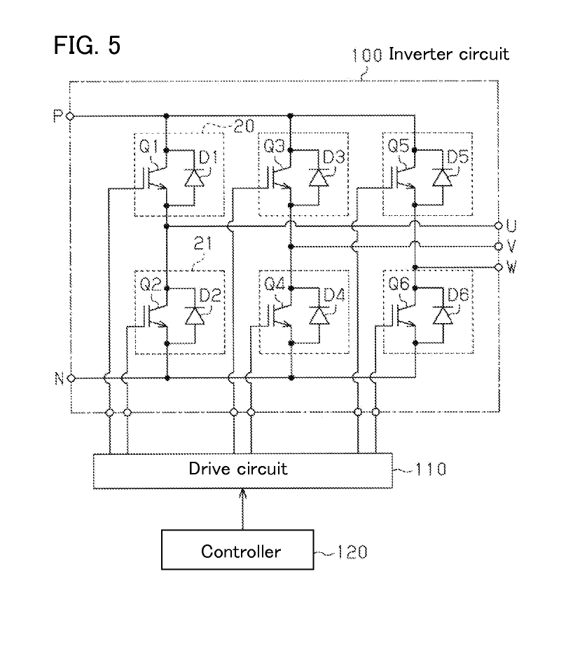

The semiconductor elements 20, 21 have therein an insulation gate bipolar transistor and a diode that form upper and lower arm elements of an inverter circuit. Referring to FIG. 5, there is shown an inverter circuit 100 for a three-phase inverter device for a vehicle. The inverter circuit 100 has six insulation gate bipolar transistors (IGBT) Q1, Q2, Q3, Q4, Q5, Q6. The gate bipolar transistor may be replaced by a power metal oxide semiconductor field effect transistor (MOSFET). Flywheel diodes D1, D2, D3, D4, D5, D6 are connected inversely parallel to the insulation gate bipolar transistors Q1, Q2, Q3, Q4, Q5, Q6, respectively.

In the inverter circuit 100, the first and second insulation gate bipolar transistors Q1, Q2, the third and fourth insulation gate bipolar transistors Q3, Q4, and the fifth and six insulation gate bipolar transistors Q5, Q6 are serially connected, respectively. The first, third, and fifth insulation gate bipolar transistors Q1, Q3, Q5 are connected to a positive input terminal P which is in turn connected to a positive electrode of a vehicle battery. The second, fourth, and sixth insulation gate bipolar transistors Q2, Q4, Q6 are connected to a negative input terminal N which is in turn connected to a negative electrode of a vehicle battery.

The junction between the insulation gate bipolar transistors Q1, Q2 forming the upper and lower arm elements for U-phase, respectively, is connected to the U-phase output of inverter circuit 100. The junction between the insulation gate bipolar transistors Q3, Q4 forming the upper and lower arm elements for V-phase, respectively, is connected to V-phase output of inverter circuit 100. The junction between the insulation gate bipolar transistors Q5, Q6 forming the upper and lower arm elements for W-phase, respectively, is connected to W-phase output of inverter circuit 100. The U-phase, V-phase, and W-phase outputs are connected to the respective inputs of a three-phase AC motor for a vehicle.

Gate terminals of the insulation gate bipolar transistors Q1 through Q6 of the inverter circuit 100 are connected to a drive circuit 110 which is in turn connected to a controller 120. Gate signals are transmitted from the drive circuit 110 to the gate terminals of the insulation gate bipolar transistors Q1 through Q6. The controller 120 controls switching operation of the insulation gate bipolar transistors Q1 through Q6 through the drive circuit 110. That is, the inverter circuit 100 converts DC power supplied by a battery to three-phase AC power having a predetermined frequency and supplies the three-phase AC power to a winding of each phase of a motor. Thus, the switching operation of the insulation gate bipolar transistors Q1 through Q6 allows three-phase AC power to be flowed in the winding of each phase of the motor for driving the motor.

The insulation gate bipolar transistor Q1 and the diode D1 that form the upper arm element for U-phase shown in FIG. 5 are incorporated in the semiconductor element 20 shown in FIGS. 1 and 2. Similarly, the insulation gate bipolar transistor Q2 and the diode D2 that form the lower arm element for U-phase shown in FIG. 5 are incorporated in the semiconductor element 21 shown in FIGS. 1 and 2.

The insulation gate bipolar transistor Q3 and the diode D3 that form the upper arm element for V-phase shown in FIG. 5 and the insulation gate bipolar transistor Q4 and the diode D4 that form the lower arm element for V-phase shown in FIG. 5 have substantially the same configuration as the semiconductor device shown in FIGS. 1 and 2. That is, the heat generated by the semiconductor element 20 having therein the insulation gate bipolar transistor Q3 and the diode D3 and by the semiconductor element 21 having therein the insulation gate bipolar transistor Q4 and the diode D4 is radiated through the radiator plate 60. The insulation gate bipolar transistor Q5 and the diode D5 that form the upper arm element for V-phase shown in FIG. 5 and the insulation gate bipolar transistor Q6 and the diode D6 that form the lower arm element for W-phase shown in FIG. 5 have substantially the same configuration as the semiconductor device shown in FIGS. 1 and 2. That is, the heat generated by the semiconductor element 20 having therein the insulation gate bipolar transistor Q5 and the diode D5 and by the semiconductor element 21 having therein the insulation gate bipolar transistor Q6 and the diode D6 is radiated through the radiator plate 60.

As shown in FIGS. 1 and 2, the entire surface of the circuit board B1 including the outer surfaces of the buffer layer 50 and the semiconductor element 20 are sealed by a resin mold 70. Similarly, the entire surface of the circuit board B2 including the outer surfaces of the buffer layer 51 and the semiconductor element 21 are sealed by a resin mold 71. As shown in FIG. 2, the upper ends of the electrodes 25, 26 extend out of and are exposed from the resin molds 70, 71, respectively.

The following will explain the method for manufacturing the semiconductor device in order. First, the circuit boards B1, B2 are made. As described above, the circuit board B1 includes the ceramic layer 40 having on one surface thereof the wiring layer 30 and on the other surface thereof the buffer layer 50 and the circuit board B2 includes the ceramic layer 41 having on one surface thereof the wiring layer 31 and on the other surface thereof the buffer layer 51.

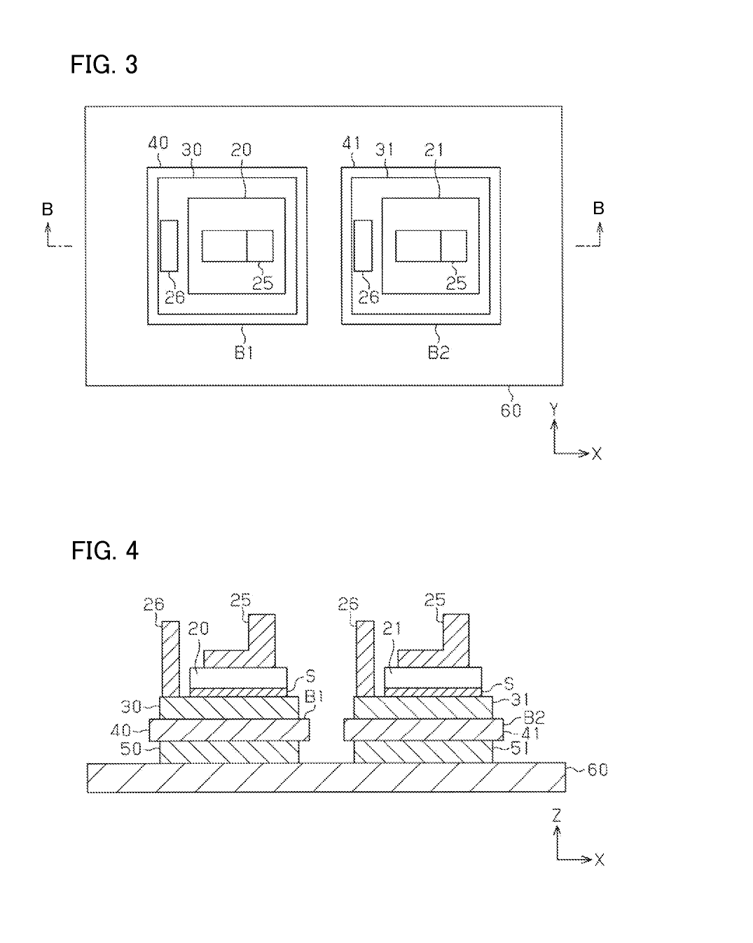

Next, the buffer layer 50 of the circuit board B1 is bonded to the radiator plate 60, as shown in FIGS. 3 and 4. Similarly, the buffer layer 51 of the circuit board B2 is bonded to the upper surface of the radiator plate 60. Thus, the circuit boards B1, B2 and the radiator plate 60 are integrated by bonding.

Then, the semiconductor element 20 is soldered to the wiring layer 30 of the circuit board B1. Similarly, the semiconductor element 21 is soldered to the wiring layer 31 of the circuit board B2. The electrode 25 is bonded at one end thereof on the upper surface of the semiconductor element 20 with the other end thereof extending upward. The electrode 26 is bonded at one end thereof on the upper surface of the wiring layer 30 with the other end thereof extending upward. Similarly, the electrode 25 is bonded at one end thereof on the upper surface of the semiconductor element 21 with the other end thereof extending upward. The electrode 26 is bonded at one end thereof on the upper surface of the wiring layer 31 with the other end thereof extending upward.

Thus, the semiconductor element 20 is bonded to the circuit board B1 and the semiconductor element 21 on the circuit board B2, respectively. Then, the entire surface of the circuit board B1 including the outer peripheral surface of the buffer layer 50 and the semiconductor element 20 are sealed by the resin mold 70, as shown in FIGS. 1 and 2. Similarly, the entire surface of the circuit board B2 including the outer peripheral surface of the buffer layer 51 and the semiconductor element 21 are sealed by the resin mold 71. The sealing by the resin molds 70, 71 is done with the upper ends of the electrodes 25, 26 exposed from the resin molds 70, 71, respectively.

The following will explain the operation of the semiconductor device 10 manufactured by the above described method. The semiconductor elements 20, 21 that generate heat, the wiring layers 30, 31 on which the semiconductor elements 20, 21 are soldered, the ceramic layers 40, 41 insulating the wiring layers 30, 31 from the radiator plate 60, the buffer layers 50, 51 reducing stress applied to the ceramic layer 40, 41, and the radiator plate 60 are integrated into a module. Such integration of components from the wiring layers 30, 31 on which the semiconductor elements 20, 21 are soldered to the radiator plate 60 improves the cooling of the semiconductor device 10. That is, the arrangement in which the circuit boards B1, B2 on which the heat generating semiconductor elements 20, 21 are soldered and the radiator plate 60 are integrated forms a direct cooling structure that cools the semiconductor elements 20, 21 effectively.

Because the entire surfaces of the circuit boards B1, B2 including the outer peripheral surfaces of the buffer layers 50, 51 and the semiconductor elements 20, 21 are sealed by the resin molds 70, 71, the thermal stress occurring due to the difference in the linear expansion coefficients between the ceramic layers 41, 41 and the radiator plate 60 and applied to the ceramic layers 40, 41 is reduced by the resin molds 70, 71. That is, the provision of the resin molds 70, 71 reduces the thermal stress applied to the ceramic layers 40, 41 due to the difference in the linear expansion coefficients between the ceramic layers 41, 41 and the radiator plate 60. Therefore, occurrence of a crack or a break in the ceramic layers 40, 41 is prevented.

The resin molds 70, 71 are provided separately for the respective circuit boards B1, B2 on the radiator plate 60. The stress occurring due to any thermal deformation in the radiator plate 60 and applied to the resin molds 70, 71 may be reduced as compared to case in which the entire area of the circuit boards B1, B2 are sealed by a common resin mold. Specifically, the amount of resin used for molding may be reduced by separate molding for the respective semiconductor elements mounted on a common radiator plate such as 60. Additionally, any stress occurring due to deformation such as bending of the radiator plate and applied to the separate resin molds is lowered as compared to a case in which a plurality of semiconductor elements is sealed by a common resin mold.

By separately sealing the circuit board B1, B2 or the semiconductor element 20, 21 by resin mold, the amount of resin mold used for each semiconductor element does not increase, so that the stress applied to each resin mold in the case of an increased number of semiconductor elements mounted on a common radiator will not increase. Additionally, the amount of the resin used for molding in the case of the above increased number of circuit boards mounted on a common radiator may be less as compared to a case in which the semiconductor elements of the circuit boards are all sealed by a single resin mold.

The semiconductor device 10 according to the above-described embodiment provides the following advantages.

(1) The semiconductor device 10 has the structure in which the entire surfaces of the circuit boards B1, B2 including the outer peripheral surfaces of the buffer layers 50, 51 and the semiconductor elements 20, 21 are sealed by the resin molds 70, 71, which helps reduce the stress applied to the ceramic layers 40, 41 in the circuit boards B1, B2 and therefore prevents occurrence of a crack or a break in the ceramic layers 40, 41.

(2) There is a fear in the semiconductor device according to the above-cited Publication having the insulation layer that is made of an organic resin as the base material for the insulation layer that the insulation layer tends to deteriorate cooling and therefore need be made large in size and also that a crack may occur in a part of the bonding layer that is not sealed by a resin mold because the laminate and the semiconductor elements are bonded to a heat sink after being sealed by a resin mold. In the present embodiment, the insulation layer that is provided by the ceramic layer provides better cooling as compared to a case in which the base material of the insulation layer is made of an organic resin, so that the size of the semiconductor device 10 may be reduced by reducing the cooling area of a part attached to the radiator plate 60, and the amount of resin used for molding can be reduced.

(3) The method for manufacturing the semiconductor device 10 includes the first and second steps. In the first step, the circuit board B1, B2 is bonded at the buffer layers 50, 51 thereof on the radiator plate 60 and the semiconductor elements 20, 21 are bonded to the wiring layers 30, 31 of the circuit boards B1, B2, respectively. In the second step, the entire surface of the circuit boards B1, B2 including the outer peripheral surface of the buffer layer 50, 51 of the circuit boards B1, B2 and the semiconductor elements 20, 21 are sealed by resin molds 70, 71, respectively. Thus, the semiconductor device 10 having the advantages that are described under the above clause (1) may be manufactured.

(4) The integration between the wiring layers 30, 31 to which the semiconductor elements 20, 21 are soldered and the radiator plate 60 helps improve cooling of the semiconductor elements 20, 21.

(5) In the structure of a semiconductor device wherein each semiconductor element is sealed independently by a resin mold, the size of the resin mold for each semiconductor element will not be increased when the number of semiconductor elements mounted on the radiator plate is increased. The structure according to the embodiment is advantageous also in that no increase occurs in the stress applied to the respective resin molds.

(6) In the structure of the semiconductor device according to the embodiment, the amount of resin used for molding when the number of semiconductor elements mounted on the radiator plate is increased may be less than in the structure wherein a plurality of semiconductor elements on the radiator plate is sealed by a single common resin mold. The present invention is not limited to the above-described embodiment, but may be modified in various ways as exemplified below.

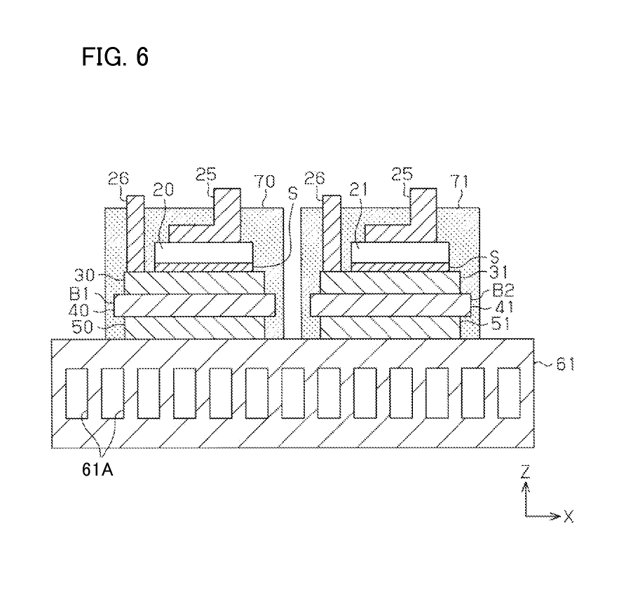

As shown in FIG. 6, a cooling device 61 of a water-cooling type may be used as the cooling member. Specifically, the water-cooling device 61 has therein a passage 61A through which refrigerant fluid is flowed for cooling the semiconductor elements 20, 21.

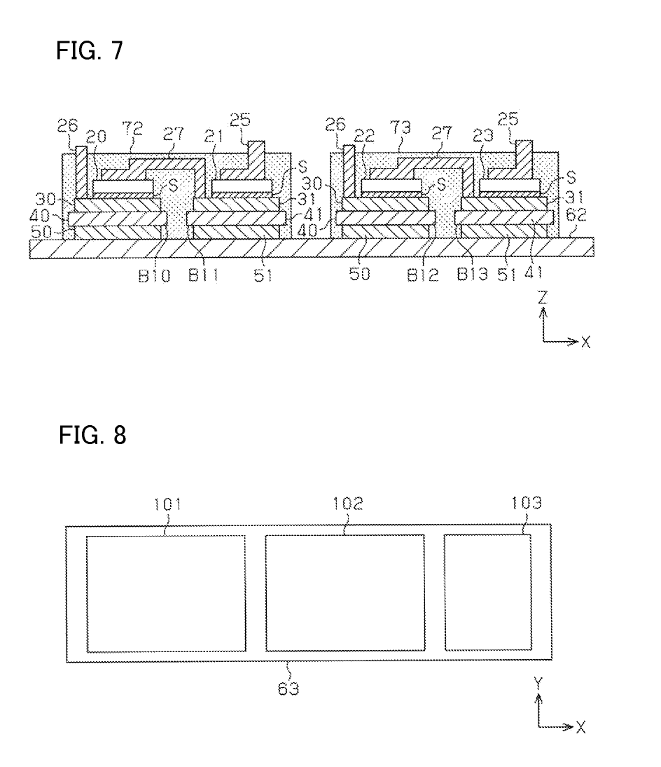

As shown in FIG. 7, the semiconductor element 20, the circuit board B10, the semiconductor element 21, and the circuit board B11 may be sealed by a resin mold 72 on a radiator plate 62. The semiconductor element 22, a circuit board B12, the semiconductor element 23, and a circuit board B13 may be sealed by a resin mold 73 on a radiator plate 62. Thus, a plural sets of semiconductor element and circuit board may be sealed by a single common resin mold as a unit. Though, in FIGS. 1 and 2, the semiconductor elements 20, 21 forming an upper arm element and a lower arm element, respectively, are sealed by separate resin molds, the semiconductor elements 20, 21 forming the upper and lower arm elements may be sealed by a single resin mold 72 and connected to each other by an electrode 27 in the resin mold 72. Similarly, the semiconductor elements 22, 23 are sealed by a single resin mold 73 and connected by the electrode 27 in the resin mold 73.

In FIG. 2, the electrodes 25, 26 extend upward and expose from the upper surfaces of the resin molds 70, 71, respectively. Alternatively, the electrodes 25, 26 may extend in the horizontal direction and expose from the lateral surfaces of the resin molds 70, 71, respectively.

As shown in FIG. 8, a plurality of inverter circuits 101, 102, 103 may be mounted on a radiator plate 63 and sealed individually by a resin mold. That is, a plurality of the inverter circuits 101, 102, 103 each having a usage different from each other may be mounted on the radiator plate 63 as a set and sealed individually by a resin mold.

Though, the semiconductor device according to the embodiments has been described as an inverter, the semiconductor device according to the present invention is applicable to any other device.

What is claimed is:

1. A semiconductor device comprising:
a circuit board including an insulation layer, a wiring layer formed on one surface of the insulation layer, and a buffer layer formed on the other surface of the insulation layer;
a semiconductor element bonded to the wiring layer;
a radiator member bonded to the buffer layer of the circuit board; and
a resin member to seal the semiconductor element and an entire surface of the circuit board including an outer peripheral surface of the buffer layer in the circuit board.

2. The semiconductor device according to claim 1, wherein the insulation layer is a ceramic layer.

3. A method for manufacturing a semiconductor device, comprising:
providing a radiator member;
providing a circuit board including an insulation layer, a wiring layer formed on one surface of the insulation layer, and a buffer layer formed on the other surface of the insulation layer;
bonding the buffer layer of the circuit board to the radiator member;
bonding the semiconductor element to the wiring layer of the circuit board; and
sealing the semiconductor element and an entire surface of the circuit board including an outer peripheral surface of the buffer layer in the circuit board with resin after the two bonding steps.

4. The method for manufacturing a semiconductor device according to claim 3, wherein the insulation layer is a ceramic layer.
